(19) United States
(12) Patent Application Publication
(10) Pub. No.: US 2006/0285607 A1
(43) Pub. Date: Dec. 21, 2006

(54) High availability narrowband channel for bandwidth efficient modulation applications

(75) Inventors: Andrew L. Strodtbeck, Marina del Rey, CA (US); Jennifer L. Vollbrecht, Torrance, CA (US)

Correspondence Address: SHIMOKAJI & ASSOCIATES, P.C., 8911 RESEARCH DRIVE, IRVINE, CA, 92618, US

(73) Assignee: THE BOEING COMPANY

(21) Appl. No.: 11/155,401

(22) Filed: Jun. 16, 2005

(51) Int. Cl. H04L 27/36; H03D 1/24; H04L 5/12

(52) U.S. Cl. 375/298; 375/320; 375/261

(57) ABSTRACT

A communication system includes a transmitter that transmits both wideband data and narrowband data on a link and a receiver that receives the wideband data and the narrowband data on the link. The receiver demultiplexes the wideband data and the narrowband data into separate data streams so that the link effects transmission of a narrowband channel and a wideband channel. The system achieves high link availability on a link using bandwidth efficient modulation by using a more robust modulation format for the narrowband channel to enable higher link availability for the narrowband channel (carrying the narrowband data on the link) than for the wideband channel. The link may employ bandwidth efficient modulation or may be compatible with prior art wideband modulation formats.

### BACKGROUND OF THE INVENTION

The present invention generally relates to radio frequency communication systems and, more particularly, to providing high link availability for a narrowband channel on a wideband bandwidth efficient modulation (BEM) radio frequency (RF) link such as a satellite link or terrestrial communications link.

Bandwidth efficient modulation (BEM) is a new approach in RF communications that achieves extremely high data rates over limited spectral allocation. BEM technology enables ultra-wideband data transfer over satellite, for example, often enabling up to five times the data throughput over a given amount of spectrum than other, more conventional techniques. Due to higher signal-to-noise ratio (SNR) requirements for BEM reception, however, a BEM channel's ability to power through severe rain attenuation events may be limited. Thus, link availability—e.g., the percentage of time that a link can provide a signal of acceptable quality for accurate reception of the transmitted signal—for a wideband BEM link may be lower than that for a lower data rate narrowband link at the same location. A small portion of the data that needs to be transmitted, however, requires a more reliable, i.e., higher availability, link than that which a wideband BEM link affords. Such data may include, for example, spacecraft telemetry and important user data, and may be transmitted over a narrowband channel.

Prior art satellite communication systems use a “bent-pipe” architecture (e.g., frequency translating repeater, or transponder) that does not incorporate sophisticated digital modulation. These bent-pipe satellites do not have sophisticated digital modulators to share spacecraft size, weight and power resources with, so with smaller payload demands they can incorporate a dedicated transmitter for narrowband channels that is designed to achieve link margins high enough to burn through all but the most extreme rain events for link availability of 99.9% and above. These narrowband transmissions use a separate part of the RF spectrum from the wideband transmissions. These systems with separate wideband and narrowband RF frequency bands require additional allocation of spectral resources and severe output filtering on the wideband channel to mitigate self-interference. Such filtering is undesireable for the much more distortion-sensitive BEM waveform. Therefore, an alternate spectral allocation would need to be found for the previous approach to be feasible.

The BEM approach with its need for higher SNR drives the satellite architecture away from previous bent-pipe systems to an architecture that demodulates and then remodulates the signal (demod-remod architecture) incorporating sophisticated digital modulation. The demod-remod architecture is favored to achieve better link performance (e.g., better SNR), since demod-remod architecture in a certain sense decouples the two links, uplink and downlink, from each other so that the downlink performance only depends on downlink SNR, and the uplink only on uplink SNR. Due to higher signal-to-noise ratio (SNR) requirements for BEM and susceptibility to rain fades, noted above, the increased RF link power requirements of BEM make the BEM type of link non-optimal for transmission of lower rate data with very high availability requirements, as high rain degradation margins (i.e., high ability to overcome rain fades) are extremely costly using BEM. The BEM architecture relies on demod-remod architecture with sophisticated digital modulation so it is not desirable to include separate downlink transmitters for the wideband BEM channel and the narrowband channel, as this would increase satellite cost. Furthermore, a separate transmission frequency for narrowband would present a spectrum allocation and self-interference challenge for a BEM satellite system.

As can be seen, there is a need for combining a narrowband channel with high availability requirements with a wideband data link—such as a BEM link—and delivering a significantly higher rain availability while minimally impacting satellite link communication hardware complexity, size, weight, power, and, therefore, cost. There is also a need for a solution to the problem of upgrading current satellite systems to BEM and other state of the art wideband communications.

### SUMMARY OF THE INVENTION

In one embodiment of the present invention, a communication system includes a transmitter that transmits both wideband data and narrowband data on a link and a receiver that receives the wideband data and the narrowband data on the link. The receiver demultiplexes the wideband data and the narrowband data into separate data streams so that the link effects transmission of a narrowband channel and a wideband channel and so that the communication system achieves higher relative availability of the narrowband channel by utilizing different modulation and error control coding formats on the narrowband data and the wideband data.

In another embodiment of the present invention, a transmitter for a communication system includes: a wideband symbol mapper that maps wideband data to wideband frames using symbols for a higher order modulation format; a narrowband symbol mapper that maps narrowband data to narrowband frames using symbols for a lower order modulation format; and a data formatter that multiplexes the narrowband frames and the wideband frames together into a single stream of coded symbols using symbols for both the higher order modulation format and the lower order modulation format.

In still another embodiment of the present invention, a receiver for a communication system includes a data demulitplexer. The data demulitplexer detects a beginning of narrowband frames in a single data stream of narrowband frames and wideband frames, in which the wideband frames comprise symbols of a wideband modulation format. The data demulitplexer separates the narrowband frames from the wideband frames. The narrowband frames comprise symbols of a narrowband modulation format that provides more reliable resolution of symbols than that for the wideband modulation format. The narrowband frames may also be sent using a lower rate code that provides more reliable resolution of symbols than that for a higher rate code used for the wideband frames.

In yet another embodiment of the present invention, a communication system includes: a wideband symbol mapper that maps wideband data to wideband frames using symbols for a first modulation format; a narrowband symbol mapper that maps narrowband data to narrowband frames using symbols for a second modulation format; a data formatter that multiplexes the narrowband frames and the wideband frames together into a single stream of coded symbols using symbols for both the first modulation format and the second modulation format; and a data demulitplexer. The data demulitplexer detects a beginning of narrowband frames in a single data stream of narrowband data coded symbols and wideband data coded symbols. The data demulitplexer separates the narrowband data coded symbols from the wideband data coded symbols. The second modulation format provides more reliable resolution of symbols than that for the first modulation format.

In a further embodiment of the present invention, a satellite communication system includes a transmitter and receiver. The transmitter includes: a wideband symbol mapper that maps wideband data to wideband frames using symbols for a first modulation format; a narrowband symbol mapper that maps narrowband data to narrowband frames using symbols for a second modulation format; a data formatter that multiplexes the narrowband frames and the wideband frames together into a single stream of coded symbols using symbols for both the first modulation format and the second modulation format; and a wideband modulator that modulates a carrier using the first modulation format and the second modulation format. The receiver has a wideband demodulator and includes a data demulitplexer. The demodulator feeds the data demulitplexer the single data stream of narrowband frames and wideband frames. The data demulitplexer detects a beginning of narrowband frames in the single data stream of narrowband data coded symbols and wideband data coded symbols and separates the narrowband data coded symbols from the wideband data coded symbols. The second modulation format provides more reliable resolution of symbols than that for the first modulation format.

In a still further embodiment of the present invention, a method for achieving high link availability on a link includes formatting narrowband data and wideband data together into a single data stream using a different symbol mapping for the narrowband data than for the wideband data to enable higher availability for a narrowband channel carrying the narrowband data on the link.

These and other features, aspects and advantages of the present invention will become better understood with reference to the following drawings, description and claims.

### BRIEF DESCRIPTION OF THE DRAWINGS

FIG. 1 is a diagram of a satellite communication system in accordance with one embodiment of the present invention;

FIG. 2 is a system block diagram showing a downlink, transmitter subsystem, in accordance with one embodiment of the present invention, for a communication system such as that shown in FIG. 1;

FIG. 3 is a data frame diagram for data transmitted in accordance with one embodiment of the present invention;

FIG. 4 is a system block diagram showing a downlink, receiver subsystem, in accordance with one embodiment of the present invention, for a communication system such as that shown in FIG. 1;

FIG. 5 is a graph of signal-to-noise ratio (SNR) vs. bit error rate (BER) illustrating one example of rain fade margins in accordance with one embodiment of the present invention;

FIG. 6 is a table presenting a relationship between link availability and rain fade margin for the example illustrated by FIG. 5; and

FIG. 7 is a flowchart of a method for achieving high link availability data transmission in a BEM link in accordance with one embodiment of the present invention.

### DETAILED DESCRIPTION OF THE INVENTION

The following detailed description is of the best currently contemplated modes of carrying out the invention. The description is not to be taken in a limiting sense, but is made merely for the purpose of illustrating the general principles of the invention, since the scope of the invention is best defined by the appended claims.

Broadly, the present invention provides a communications downlink for a communication system, such as radio frequency (RF) communications over a satellite link or over a ground link, where the link is subject to interference from atmospheric disturbances such as rain, and where two different types of data are to be transmitted over two channels with different data rates and different quality of service (QoS) requirements. The two channels, for example, may be a narrowband channel with a lower data rate and wideband channel with a higher data rate, the narrowband channel having higher availability requirements than the wideband channel because, for example, of the type of data to be transmitted—such as spacecraft telemetry, or important user data. In one embodiment, the two channels of data are combined into one coded symbol stream and sent over a wideband satellite link to provide high link availability for the narrowband channel on the wideband link while providing generally lower link availability for the wideband channel on the same wideband link. In one particular embodiment, the wideband link may be an RF bandwidth efficient modulation (BEM) satellite link that provides high link availability for a narrowband channel and the same or lower link availability for a wideband channel on the wideband BEM satellite link.

In another embodiment, a satellite communications downlink combines a narrowband channel with high availability requirements with a wideband BEM data link (which may have lower availability requirements); delivers significantly higher rain availability while minimally impacting satellite link communication hardware complexity, size, weight, power, and, therefore, cost; and provides a simple, elegant solution to the problem of upgrading current satellite systems to BEM. For example, one embodiment makes novel use of existing spacecraft resources to apply coding and modulation to the narrowband channel and multiplex with the wideband coded data, eliminating need for additional hardware and spectral allocation for high availability narrowband data.

By combining channels on a single link using only one transmitter and receiver, one embodiment of the present invention differs from prior art communication systems that provide separate links, separate transmitters and receivers for each channel. As described above such prior art approaches are impractical for implementing high availability, wideband (e.g., BEM) communication links.

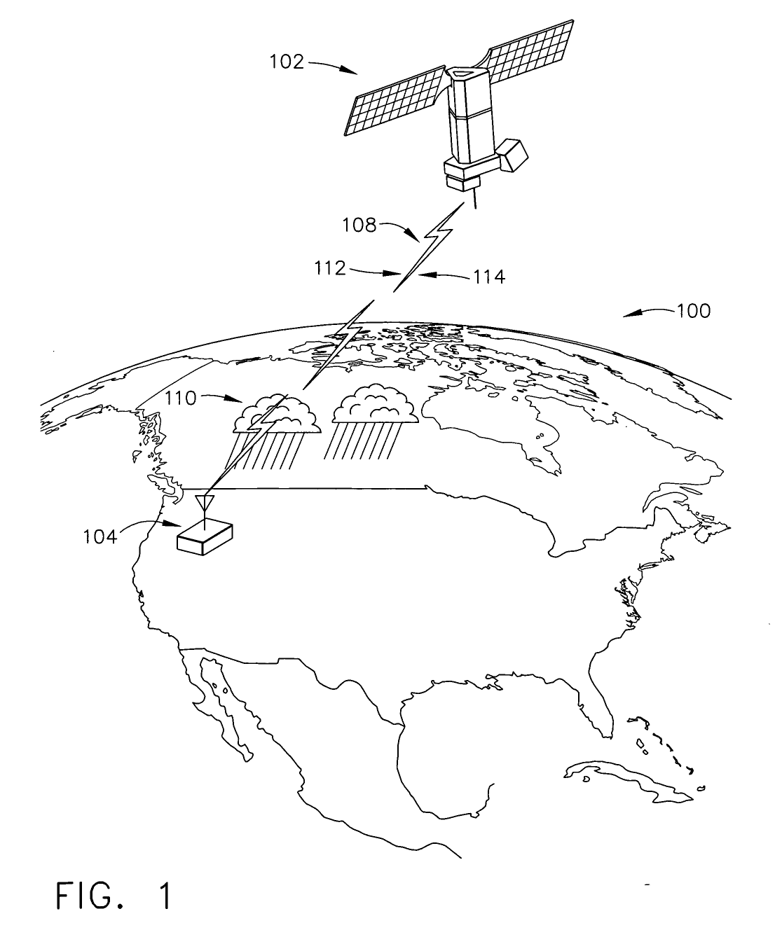

FIG. 1 illustrates a communication system 100 in accordance with one embodiment of the present invention. Communication system 100 may include a satellite 102 having RF communications equipment—such as transmitters and receivers—for communication with a ground station 104 over link 108. Link 108 may be subject to rain fade phenomena caused by atmospheric disturbances such as rain 110 and other factors affecting link availability, e.g., the percentage of time that a rain loss power allocation is not exceeded—as illustrated, for example, in FIG. 6. Link 108 may include a narrowband channel 112 and a wideband channel 114.

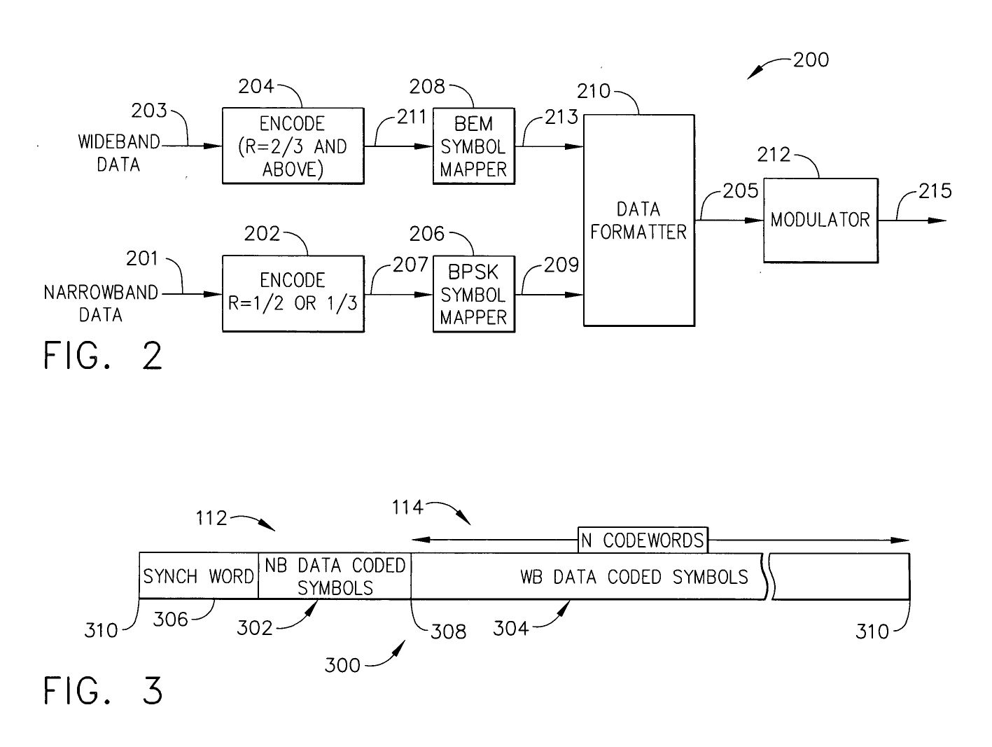

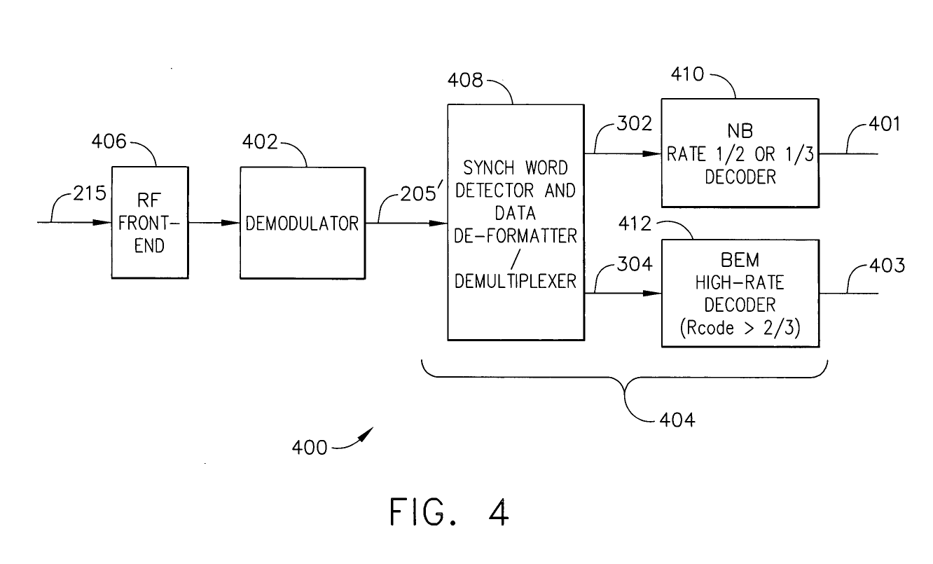

Referring now to FIGS. 2, 3, and 4, FIG. 2 illustrates a transmitter 200 for combining—e.g., by multiplexing—narrowband data 201 and wideband data 203 into a single stream 205 of coded symbols in accordance with one embodiment of the present invention. FIG. 3 illustrates a data code block 300 including narrowband coded frame 302 and wideband coded frame 304 included in the stream 205 of coded symbols. FIG. 4 illustrates a receiver 400 for receiving the single stream 205 of coded symbols and demultiplexing stream 205 into a stream of narrowband data 401 corresponding to narrowband data 201 and a stream of wideband data 403 corresponding to wideband data 203. For example, narrowband data 401 may reconstruct narrowband data 201 to within some specific bit error rate (BER) and, similarly, for wideband data 403 with regard to wideband data 203.

In one embodiment, for example, transmitter 200 may be a sophisticated BEM digital transmitter 200 that may provide a high availability narrowband channel 112 for BEM applications by muliplexing narrowband data 201 and wideband data 203. Narrowband channel 112 may comprise, for example, narrowband coded frames 302, as shown in FIG. 3, and wideband channel 114 may comprise wideband coded frames 304. Narrowband coded frames 302 may be encoded from narrowband data 201 and wideband coded frames 304 may be encoded from wideband data 203. Narrowband coded frames 302 and wideband coded frames 304 may be multiplexed to form data code block 300 as shown in FIG. 3. The multiplexing may include insertion into each data code block 300 of a unique word 306, e.g., a word that will not otherwise occur as data so that it can be used, for example, to identify the beginning (e.g., data code block boundary 310) of each data code block 300. Such a unique word 306 may also be used, for example, for synchronization of receiver 400 with transmitter 200 and may be referred to as a “synch” word.

Higher availability may be achieved on the narrowband channel 112 than on the wideband channel 114 by (1) using lower order modulation format—such as BPSK (binary phase shift keyed) or QPSK (quaternary phase shift keyed) symbols—compared to higher order modulation formats—such as 12-4 APK (amplitude phase keyed) symbols, 64-QAM (quadrature amplitude modulation), 256-QAM, and so on; and (2) using lower rate forward error correction (FEC) coding—such as rate 1/2 or rate 1/3 FEC—compared to higher rate, more bandwidth efficient, FEC coding—such as rate 2/3 FEC and above. Lower order modulation formats may be described as placing symbols farther apart in an in-phase, quadrature (I/Q) phase space so that resolution of one symbol from the next closest symbol in the space may be more reliably achieved than for higher order modulation formats. Coding rate may be described as the ratio of input information bits to output information bits of coded data so that the lower the rate the more bits are used to convey the same amount of information. Thus, a lower rate code may also increase the reliability of information transmission.

Operation of one embodiment may be summarized as multiplexing short bursts of less bandwidth-efficiently modulated and encoded data with long bursts of wideband data. Wideband data is typically bandwidth-efficiently modulated and coded, although it may be desired to transmit backwards-compatible waveforms that may not be bandwidth-efficiently modulated. A summary of several of the factors involved may be given as follows:
(1) Lower bandwidth efficient modulation may use more robust signaling sets (i.e., transmitted symbols are farther separated in signal space, thus more robust to noise and distortion effects) and can be transmitted at low signal-to-noise ratio (SNR).
(2) Higher bandwidth efficient modulation may use more tightly packed signaling sets that may be less robust to noise and distortion (i.e., smaller amounts of noise and/or distortion will confuse one transmitted symbol with another) and generally requires higher SNR.
(3) Lower bandwidth efficient FEC refers to using lower rate FEC coding so that more redundancy is added into the data stream (e.g., more channel symbols must be transmitted to represent each information bit) and can operate with lower SNR at the expense of data rate.
(4) Higher bandwidth efficient FEC refers to using higher rate FEC coding so that less redundancy is added into the data stream and generally requires operating with higher SNR than for lower rate codes, but sacrifices less data throughput.
(5) A wideband data stream needs to operate above a particular (minimum) SNR to operate at or above a particular (minimum) availability.
   Higher availability requirements for narrowband appear to imply needing more power to get better SNR margin to overcome communication link fades. Providing more power, especially for satellite applications, may be economically or physically impractical or impossible. An embodiment of the present invention provides a novel approach to achieve the required availability while operating at the same or lower SNR without increasing power through the use, for example, of more robust waveforms (modulation formats) and coding (e.g., FEC coding).

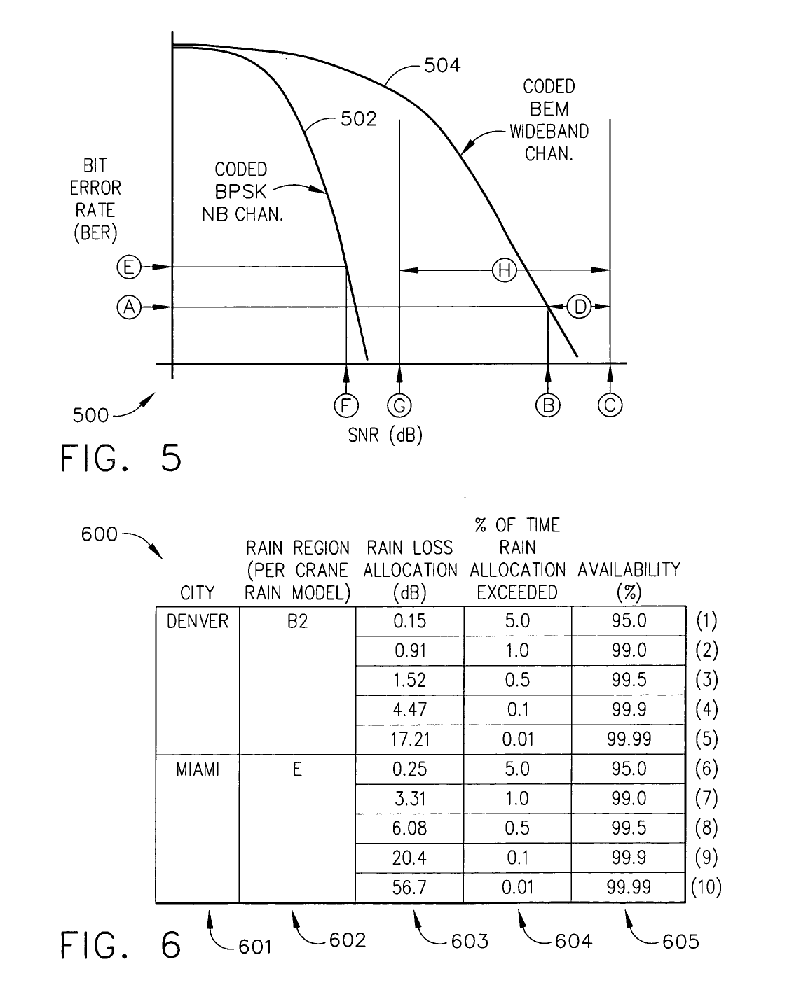

One embodiment may be described as taking advantage of the ability of a wideband demodulator—such as a BEM demodulator 402 of a receiver 400 in one example embodiment—to maintain tracking through extremely deep fades—such as those caused by atmospheric disturbances, as described above. In the exemplary embodiment, advantage is taken of the fact that the coded BPSK data—e.g., narrowband coded frames 302- requires much lower signal-to-noise ratio (SNR) to achieve acceptable bit error rate than the coded BEM waveform—e.g., wideband coded frames 304. As shown in the example given below and illustrated by FIGS. 5 and 6, the BEM receiver demodulator 402 may be capable of tracking clock and carrier recovery through fades, i.e., reductions in SNR measured in decibels (dB), for which the narrowband BPSK data will be recoverable at far deeper fades than the wideband BEM data, so that significantly increased availability may be delivered for the narrowband channel compared to the wideband channel.

Continuing with FIG. 2, digital transmitter 200 may apply an FEC code at encoding module 202 to the narrowband data 201. The narrowband data 201 may be FEC encoded with a rate 1/2 or 1/3 code, for example, if a very high level of performance is required, or the rate could be higher, such as rate 2/3 if such a high level of performance is not required. The FEC encoding performed at encoding module 202 also may be an iterative block (i.e., “turbo”) code, as known in the art. Likewise, digital transmitter 200 may apply an FEC code at encoding module 204 to the wideband data 203. The wideband data 203 may be FEC encoded with a higher rate code—such as a rate 2/3 code or higher—because the BEM wideband data must be transmitted bandwidth-efficiently, and thus the additional redundancy added to the data stream by the encoding function is kept to a minimum. The FEC encoding performed at encoding module 204 also may be an iterative block (i.e., “turbo”) code, as known in the art.

Transmitter 200 at symbol mapper 206 may format the narrowband encoded data 207 for a low order of modulation, for example, as binary phase shift keyed (BPSK) symbols, one for in-phase (I) and one for quadrature (Q), corresponding to BPSK symbols, mapping the encoded data 207 to digital words, e.g., narrowband data coded symbols 209. Narrowband data coded symbols 209 may be comprised of any symbols in phase space, BPSK symbols being used as one illustrative example. Symbol mapper 206 may output narrowband data coded symbols 209 to data formatter 210. Likewise, transmitter 200 at symbol mapper 208 may format the wideband encoded data 211 for a higher order of modulation, for example, 12-4 APK or 64-QAM, mapping the encoded data 211 to digital words, e.g., wideband data coded symbols 213, which may be comprised of higher order modulation symbols corresponding to the modulation used, for example, 12-4 APK or 64-QAM. Symbol mapper 208 may output wideband data coded symbols 213 to data formatter 210.

The narrowband data coded symbols 209 may be inserted by data formatter 210 between wideband data coded symbols 213 into wideband data code blocks—such as data code block 300 seen in FIG. 3—which may also include narrowband coded frames 302 and wideband coded frames 304 along with, or in place of, a BPSK unique word 306 (see FIG. 3, where narrowband coded frames 302 may include narrowband data coded symbols 209 and wideband coded frames 304 may include wideband data coded symbols 213) to produce a single stream 205 of coded symbols having symbols for both the wideband and narrowband modulation formats. The multiplexing operation of data formatter 210 may be described as multiplexing into the data stream very short bursts of narrowband data—e.g., approximately 1% or so of the data—at a less bandwidth-efficient modulation and coding (lower code rates=higher redundancy=less bandwidth-efficient) that require much lower SNR for accurate signal reconstruction, along with much longer bursts of wideband data at a more bandwidth-efficient modulation format—the format may be BEM or may be backwards-compatible with previously used waveforms—and coding (higher code rates (rate 2/3 and above)=lower redundancy=more bandwidth-efficient) that require higher SNR to accurately reconstruct. Thus, the narrowband data will be capable of being reconstructed at much lower SNR's (higher fades) than the wideband data and will have a much higher link availability.

The unique word 306 may be included in data code block 300 and may permit synchronization and location of wideband data code block boundaries—such as boundaries 308 and 310. These unique words—such as unique word 306, may enable synchronization of the decoder, e.g., decoder 404 of receiver 400 shown in FIG. 4, and may also be used to assist clock and carrier recovery at the receiver, which may be functions of RF front end 406 and demodulator 402 of receiver 400, for example. The single stream 205 of coded symbols, e.g., data code blocks 300, may be input to a modulator 212 and used to modulate a carrier 215 for transmission over link 108. Thus, the BEM modulator (e.g., transmitter 200) functionality may include FEC encoding, symbol mapping, pulse shaping, framing and other waveform processing to enable reliable transmission of higher order modulations (e.g., 12-4 APK, 64 QAM, etc.) over a satellite link—such as link 108.

Receiver 400, shown in FIG. 4, may include an RF front end 406 that receives modulated carrier 215 and prepares it for demodulator 402. Demodulator 402 may provide a reconstructed stream 205′ of coded symbols, e.g., data code blocks 300, to decoder 404, which may include a data demultiplexer 408. Data demultiplexer 408 may detect unique word 306 of each data code block 300 of stream 205′ of coded symbols and may determine the location of data code block boundaries, for example, boundary 308 at the beginning of the block of wideband coded frames 304 and boundary 310 at the end of the block of wideband coded frames 304. Data demultiplexer 408 may use boundary 308, for example, to determine when to stop feeding narrowband coded frames 302 to narrowband channel FEC decoder 410 and begin feeding wideband coded frames 304 to wideband channel FEC decoder 412, thereby demuliplexing stream 205′ of coded symbols, e.g., separating the narrowband coded frames 302 from the wideband coded frames 304. Narrowband channel, low rate FEC decoder 410 may decode coded frames 302 into narrowband data 401 corresponding to original narrowband data 201 and wideband channel, high rate FEC decoder 412 may decode coded frames 304 into wideband data 403 corresponding to original wideband data 203. Thus, a narrowband channel 112 may be added to a wideband channel 114 on link 108 in such a way that the narrowband channel 112 achieves a higher availability than is afforded to BEM wideband channel 114.

### EXAMPLE

FIG. 5 shows a graph 500 with signal-to-noise ratio (SNR) on the abscissa and bit error rate (BER) on the ordinate illustrating one example of rain fade margins for a narrowband channel—such as narrowband channel 112—at curve 502 and a wideband channel—such as wideband channel 114—at curve 504, in accordance with one embodiment of the present invention. The lettered items in FIG. 5 may be interpreted as follows:
(A) Required BER for wideband BEM channel;
(B) BEM SNR at required BER;
(C) Nominal link SNR without rain;
(D) Approximate rain fade margin for wideband BEM channel=(C)−(B);
(E) Required BER for narrowband channel [note: could be above or below (A)];
(F) Narrowband SNR at required BER;
(G) Receiver loop tracking dropout SNR [note: could be to right or left of (F)];
(H) Approximate rain fade margin for narrowband channel=(C)−max((F),(G)).

Referring to table 600 shown in FIG. 6, a particular example illustrated by FIG. 5 may be given as follows. Suppose margin (D)=2.0 dB and (H)=20 dB (see column 603 of table 600, lines 3 and 5 for approximate values). Then for a receive site in Denver (see column 601), the BEM wideband channel (channel 114) availability is approx. 99.5%, and the narrowband channel (channel 112) availability is approx. 99.99% (see column 605, lines 3 and 5). This means that the BEM wideband channel 114 will experience a rain loss greater than its margin and experience an outage approximately 0.5% of the time, while the narrowband channel 112 outage time is less than 0.01% (see column 604).

For Miami (again see column 601), with its higher probability of more severe rain fade (according to the Crane Rain Model, see column 602), the same margins (D)=2.0 dB and (H)=20 dB (see column 603 of table 600, interpolate between lines 6 and 7 for D, approximate line 9 for H) imply that the availabilities are, respectively, less than 99.0% and 99.9% for the BEM wideband channel 114 and the narrowband channel 112 (see column 605). This means that the BEM wideband channel 114 will experience a rain loss greater than its margin and experience an outage greater than 1.0% of the time, while the narrowband channel 112 outage time is approximately 0.1% (see column 604).

In both cases, the FEC coding and lower order modulation format for the narrowband channel 112 enable it to perform with a significantly higher availability (significantly less outages) than the BEM wideband channel 114. For example, in the first example above, the narrowband channel performance may be described as being higher by a factor of about 50 (ratio of outage percentages of narrowband to wideband), and in the second example above, the narrowband channel performance may be described as being higher by a factor of about 10. Thus, between the two examples, narrowband channel performance may be described as being higher by a factor of at least about 10.

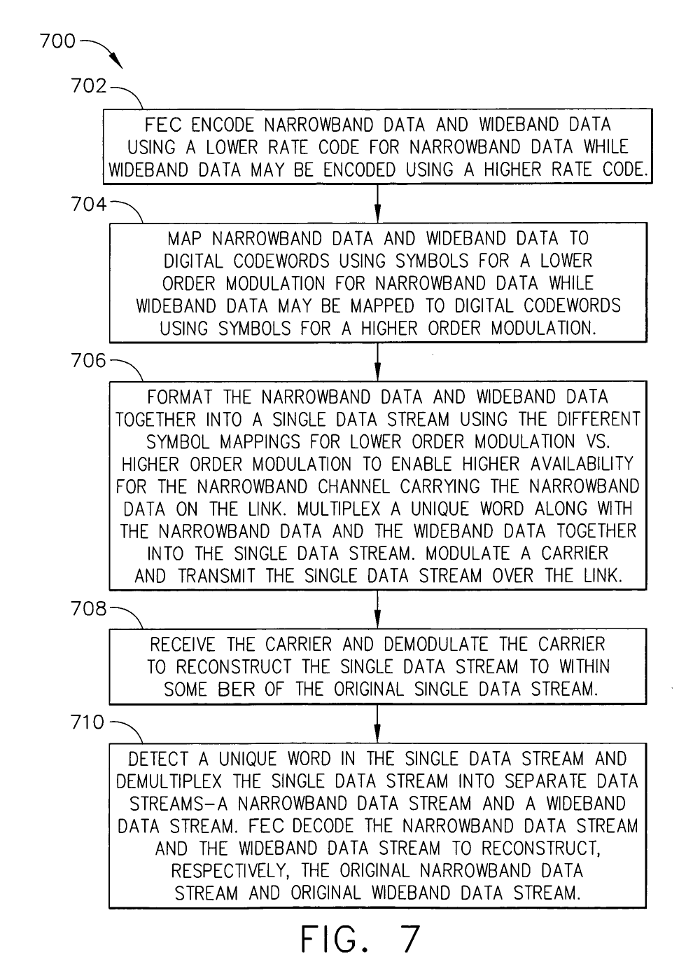

FIG. 7 illustrates method 700 for adding a narrowband channel—such as narrowband channel 112—to a wideband channel—such as wideband channel 114 on a link—such as link 108—in such a way that the narrowband channel may achieve a higher availability than may be afforded to the wideband channel. At operation 702, narrowband data 201 may be FEC encoded using a lower rate code while wideband data 203 may be encoded using a higher rate code. At operation 704, narrowband data 201 may be mapped to digital narrowband data coded symbols 209 using symbols for a lower order modulation while wideband data 203 may be mapped to digital wideband data coded symbols 213 using symbols for a higher order modulation. At operation 706, the narrowband data and wideband data may be formatted together into a single data stream 205 of coded symbols using the different symbol mappings—e.g., for lower order modulation vs. higher order modulation—to enable higher availability for the narrowband channel 112 carrying the narrowband data 201 on the link 108. Operation 706 may include multiplexing a unique word along with the narrowband data 201 and the wideband data 203 together into data stream 205. Operation 706 may also include modulating a carrier 215 and transmitting the data stream 205 over the link 108. Operation 708 may include receiving the carrier 215 and demodulating the carrier to reconstruct data stream 205′ of coded symbols to within some BER of original data stream 205 of coded symbols. Operation 710 may include detecting a unique word in the data stream 205′ and demultiplexing the data stream 205′ into separate data streams—a narrowband data stream and wideband data stream which may be FEC decoded to reconstruct narrowband data stream 401 and wideband data stream 403 corresponding, respectively, to original narrowband data stream 201 and original wideband data stream 203.

It should be understood, of course, that the foregoing relates to exemplary embodiments of the invention and that modifications may be made without departing from the spirit and scope of the invention as set forth in the following claims.

We claim:

1. A communication system comprising:
a transmitter that transmits both wideband data and narrowband data on a link;
a receiver that receives said wideband data and said narrowband data on said link, and demultiplexes said wideband data and said narrowband data into separate data streams so that said link effects transmission of a narrowband channel and a wideband channel and said communication system achieves higher relative availability of said narrowband channel by utilizing different modulation and error control coding formats on said narrowband data and said wideband data.

2. The communication system of claim 1 wherein:
said transmitter includes a first symbol mapper that maps the narrowband data to symbols of a first modulation format and a second symbol mapper that maps wideband data to symbols of a second modulation format, wherein said first modulation format provides more reliable resolution of symbols than said second modulation format.

3. The communication system of claim 1 wherein:
said transmitter includes a first symbol mapper that maps the narrowband data to symbols of a first modulation format and a second symbol mapper that maps wideband data to symbols of a second modulation format, wherein said first modulation format provides more reliable resolution of symbols than said second modulation format; and
said transmitter includes a data formatter that multiplexes said symbols of said first modulation format and said symbols of said second modulation format into a single bandwidth efficient modulation data stream.

4. The communication system of claim 1 wherein:
said transmitter includes a first symbol mapper that maps the narrowband data to symbols of a first modulation format and a second symbol mapper that maps wideband data to symbols of a second modulation format, wherein said first modulation format provides more reliable resolution of symbols than said second modulation format; and
said transmitter includes a data formatter that:
multiplexes said symbols of said first modulation format and said symbols of said second modulation format into a single bandwidth efficient modulation data stream, and
inserts a unique word of symbols of said first modulation format into said single bandwidth efficient modulation data stream.

5. The communication system of claim 1 wherein:
a first link availability of said link for said narrowband channel is higher than a second link availability of said link for said wideband channel.

6. The communication system of claim 1, further comprising:
a first FEC encoder that FEC encodes said narrowband data and a second FEC encoder that FEC encodes said wideband data.

7. The communication system of claim 6 wherein:
said narrowband data is FEC encoded at a lower rate than that at which said wideband data is FEC encoded.

8. A transmitter for a communication system, comprising:
a wideband symbol mapper that maps wideband data to wideband frames using symbols for a higher order modulation format;
a narrowband symbol mapper that maps narrowband data to narrowband frames using symbols for a lower order modulation format;
a data formatter that multiplexes said narrowband frames and said wideband frames together into a single stream of coded symbols using symbols for both said higher order modulation format and said lower order modulation format.

9. The transmitter of claim 8 wherein:
a narrowband link availability for said narrowband frames using symbols for said lower order modulation format is significantly higher than a wideband link availability for said wideband frames using symbols for said higher order modulation format.

10. The transmitter of claim 8 wherein:
a bandwidth efficient modulation modulator is used to modulate a carrier with both said symbols for said lower order modulation format and said symbols for said higher order modulation format.

11. The transmitter of claim 8 wherein:
said lower order modulation format is binary phase shift keying (BPSK).

12. The transmitter of claim 8 wherein:
said higher order modulation format is chosen from quadrature amplitude modulation (QAM) or amplitude phase keying (APK).

13. The transmitter of claim 8 wherein:
said data formatter multiplexes a unique word for synchronization into said single stream of coded symbols.

14. The transmitter of claim 8 further including a high rate FEC encoder that FEC encodes said wideband data.

15. The transmitter of claim 8 further including a low rate FEC encoder that FEC encodes said narrowband data.

16. A receiver for a communication system, comprising:
a data demulitplexer wherein:
said data demulitplexer detects a beginning of narrowband frames in a single data stream of narrowband frames and wideband frames, said wideband frames comprising symbols of a wideband modulation format; and
said data demulitplexer separates said narrowband frames from said wideband frames; and
wherein said narrowband frames comprise symbols of a narrowband modulation format that provides more reliable resolution of symbols than that for the wideband modulation format of the symbols of said wideband frames.

17. The receiver of claim 16 wherein:
a narrowband channel performance for a narrowband channel comprising said narrowband frames is higher by a factor of at least about 10 than a wideband channel performance for a wideband channel comprising said wideband frames.

18. The receiver of claim 16 wherein:
said data demulitplexer feeds said wideband frames to a wideband FEC decoder; and
said wideband FEC decoder decodes for an FEC code at rate greater than or equal to 2/3.

19. The receiver of claim 16 wherein:
said data demulitplexer feeds said narrowband frames to a narrowband FEC decoder; and
said narrowband FEC decoder decodes for an FEC code at rate less than 2/3.

20. The receiver of claim 16 further comprising:
a bandwidth efficient modulation demodulator that demodulates a carrier and feeds both said wideband frames comprising symbols of said wideband modulation format and said narrowband frames comprising symbols of said narrowband modulation format to said data demulitplexer.

21. A communication system comprising:
a wideband symbol mapper that maps wideband data to wideband frames using symbols for a first modulation format;
a narrowband symbol mapper that maps narrowband data to narrowband frames using symbols for a second modulation format;
a data formatter that multiplexes said narrowband frames and said wideband frames together into a single stream of data coded symbols using symbols for both said first modulation format and said second modulation format;
a data demulitplexer wherein:
said data demulitplexer detects a beginning of narrowband frames in the single data stream of narrowband data coded symbols and wideband data coded symbols, said wideband data coded symbols comprising symbols of said first modulation format and said narrowband data coded symbols comprising symbols of said second modulation format; and
said data demulitplexer separates said narrowband data coded symbols from said wideband data coded symbols, and
wherein said second modulation format provides more reliable resolution of symbols than that for said first modulation format.

22. The communication system of claim 21, wherein said data formatter said single stream as a series of data code blocks with a synch word at the beginning of each data code block.

23. The communication system of claim 21, wherein said second modulation format is binary phase shift keying (BPSK).

24. The communication system of claim 22, wherein said synch word is a binary phase shift keying (BPSK) word.

25. A satellite communication system, comprising:
a transmitter including:
a wideband symbol mapper that maps wideband data to wideband frames using symbols for a first modulation format;
a narrowband symbol mapper that maps narrowband data to narrowband frames using symbols for a second modulation format;
a data formatter that multiplexes said narrowband frames and said wideband frames together into a single stream of coded symbols using symbols for both said first modulation format and said second modulation format; and
a wideband modulator that modulates a carrier using said first modulation format and said second modulation format; and
a receiver having a wideband demodulator and including:
a data demulitplexer wherein:
said data demulitplexer receives from said demodulator a reconstructed single data stream of narrowband frames and wideband frames, said wideband frames comprising data coded symbols of said first modulation format and said narrowband frames comprising data coded symbols of said second modulation format;
said data demulitplexer detects a beginning of narrowband frames in said reconstructed single data stream of narrowband frames of data coded symbols and wideband frames of data coded symbols; and
said data demulitplexer separates said narrowband data coded symbols from said wideband data coded symbols, and
wherein said second modulation format provides more reliable resolution of symbols than that for said first modulation format.

26. A method for achieving high link availability on a link, comprising the step of:
formatting narrowband data and wideband data together into a single data stream using a different symbol mapping for the narrowband data than for the wideband data to enable higher availability for a narrowband channel carrying the narrowband data on the link.

27. The method of claim 26, further comprising:
placing a unique word in the single data stream using the symbol mapping for the narrowband data.

28. The method of claim 26, further comprising:
formatting said narrowband data with a lower order modulation format and formatting said wideband data with a higher order modulation format.

29. The method of claim 28, wherein:
said lower order modulation format is binary phase shift keying (BPSK).

30. The method of claim 27, wherein:
said unique word is a binary phase shift keying (BPSK) word.

31. The method of claim 26, further comprising:
FEC encoding the narrowband data.

32. The method of claim 26, further comprising:
FEC encoding the wideband data at a first code rate; and
FEC encoding the narrowband data at a second code rate which is lower than the first code rate.
